(19) United States
(12) Patent Application Publication
(10) Pub. No.: US 2024/0194643 A1
(43) Pub. Date: Jun. 13, 2024

(54) SEMICONDUCTOR PACKAGE INCLUDING A PLURALITY OF DIFFERENT STACKED CHIPS AND METHOD OF MANUFACTURING THE SEMICONDUCTOR PACKAGE

(71) Applicant: SAMSUNG ELECTRONICS CO., LTD., Suwon-si (KR)

(72) Inventor: Youngdeuk KIM, Suwon-si (KR)

(21) Appl. No.: 18/524,094

(22) Filed: Nov. 30, 2023

(30) Foreign Application Priority Data
Dec. 13, 2022 (KR) 10-2022-0173344

(51) Int. Cl. H01L 25/065; H01L 23/00

(52) U.S. Cl. CPC H01L 25/0652; H01L 24/03; H01L 24/05; H01L 24/06; H01L 24/13; H01L 24/14; H01L 24/16; H01L 24/17; H01L 24/32; H01L 24/73; H01L 2224/03462; H01L 2224/05155; H01L 2224/0603; H01L 2224/06519; H01L 2224/1358; H01L 2224/13647; H01L 2224/13655; H01L 2224/1403; H01L 2224/14519; H01L 2224/16148; H01L 2224/16225; H01L 2224/1703; H01L 2224/17519; H01L 2224/32145; H01L 2224/32225; H01L 2224/73204; H01L 2924/1431; H01L 2924/1436; H01L 2924/1438; H01L 2924/181

(57) ABSTRACT

A semiconductor package includes: a first semiconductor chip including a first substrate, first through electrodes, first signal bonding pads electrically connected to the first through electrodes, and first dummy bonding pads electrically insulated from the first through electrodes, wherein the first through electrodes penetrate the first substrate; a second semiconductor chip stacked on the first semiconductor chip and including a second substrate and a plurality of second chip pads on the second substrate and respectively corresponding to the first signal bonding pads and the first dummy bonding pads; first conductive bumps between the first signal bonding pads and the corresponding second chip pads; and second conductive bumps between the first dummy bonding pads and the corresponding second chip pads, wherein the first conductive bumps include a signal bump pad and a first solder bump, and the second conductive bumps include a thermal bump pad and a second solder bump.

### CROSS-REFERENCE TO RELATED APPLICATION

This application claims priority under 35 U.S.C. § 119 to Korean Patent Application No. 10-2022-0173344, filed on Dec. 13, 2022 in the Korean Intellectual Property Office (KIPO), the disclosure of which is incorporated by reference herein in its entirety.

### TECHNICAL FIELD

Example embodiments of the present inventive concept relate to a semiconductor package and a method of manufacturing the semiconductor package. More particularly, example embodiments of the present inventive concept relate to a semiconductor package including a plurality of different stacked chips and a method of manufacturing the same.

### DISCUSSION OF THE RELATED ART

Generally, electronic devices may include a high bandwidth memory (HBM) or a stacked chip package to provide high performances such as a high capacitance and a high speed operation. Since the HBM memory device used in such an electronic device typically includes vertically stacked chips, it may be desirable to reduce and dissipate heat within the HBM memory device. Further, HBM memory devices including conductive bumps have been under development to reduce and dissipate heat therein.

### SUMMARY

According to an example embodiment of the present inventive concept, a semiconductor package includes: a first semiconductor chip including a first substrate having a first surface and a second surface opposite to the first surface, first through electrodes, first signal bonding pads, and first dummy bonding pads, wherein the first through electrodes penetrate the first substrate, wherein the first signal bonding pads are provided on the second surface and are electrically connected to the first through electrodes, and wherein the first dummy bonding pads are provided on the second surface and are electrically insulated from the first through electrodes; a second semiconductor chip stacked on the second surface of the first semiconductor chip, wherein the second semiconductor chip includes a second substrate having a third surface and a fourth surface opposite to the third surface and a plurality of second chip pads that are provided on the third surface and that are respectively corresponding to the first signal bonding pads and the first dummy bonding pads; first conductive bumps interposed between the first signal bonding pads and the corresponding second chip pads; and second conductive bumps interposed between the first dummy bonding pads and the corresponding second chip pads, wherein each of the first conductive bumps includes a signal bump pad and a first solder bump, wherein the signal bump pad is provided on a second chip pad of the plurality of second chip pads and has a dimple in an upper portion thereof, and wherein the first solder bump is provided on the signal bump pad, and each of the second conductive bumps includes a thermal bump pad and a second solder bump, wherein the thermal bump is provided on a second chip pad of the plurality of second chip pads and has a flat upper surface, and wherein the solder bump is provided on the thermal bump pad.

According to an example embodiment of the present inventive concept, a semiconductor package includes: first, second, third and fourth semiconductor chips sequentially stacked on one another via conductive connection members, wherein each of the first, second, third and fourth semiconductor chips includes a substrate having a first surface and a second surface opposite to each other, and signal chip pads and dummy chip pads provided on the first surface of the substrate, wherein each of the conductive connection members include first conductive bumps and second conductive bumps, wherein the first conductive bumps are disposed on the signal chip pads, and wherein second conductive bumps are disposed on the dummy chip pads, wherein each of the first conductive bumps includes a signal bump pad and a first solder bump, wherein the signal bump pad is provided on the signal chip pad and has a dimple in an upper portion thereof, and wherein the first solder bump is provided on the signal bump pad, and wherein each of the second conductive bumps includes a thermal bump pad and a second solder bump, wherein the thermal bump pad is provided on the dummy chip pad and has a flat upper surface, and wherein the second solder bump is provided on the thermal bump pad.

According to an example embodiment of the present inventive concept, a semiconductor package includes: a buffer die; first, second, third and fourth memory dies sequentially stacked on the buffer die via conductive connection members; and adhesive layers disposed between the first to fourth memory dies and attaching the first, second, third and fourth memory dies to each other, wherein each of the first, second, third and fourth memory dies includes a substrate having a first surface and a second surface opposite to the first surface and signal chip pads and dummy chip pads provided on the substrate, wherein the conductive connection members include first conductive bumps and second conductive bumps, wherein the first conductive bumps are disposed on the signal chip pads, and the second conductive bumps are disposed on the dummy chip pads, wherein each of the first conductive bumps includes a signal bump pad and a first solder bump, wherein the signal bump pad is provided on the signal chip pad and has a dimple in an upper portion thereof, and the first solder bump is provided on the signal bump pad, and wherein each of the second conductive bumps includes a thermal bump pad and a second solder bump, wherein the thermal bump pad is provided on the dummy chip pad and has a flat upper surface, and the second solder bump is provided on the thermal bump pad.

### BRIEF DESCRIPTION OF THE DRAWINGS

The above and other features of the present inventive concept will become more apparent by describing in detail example embodiments thereof, with reference to the accompanying drawings, in which:

FIG. 1 is a cross-sectional view illustrating an electronic device in accordance with an example embodiment of the present inventive concept.

FIG. 2 is a cross-sectional view illustrating a semiconductor package in accordance with an example embodiment of the present inventive concept.

FIG. 3 is an enlarged cross-sectional view illustrating portion ‘A’ in FIG. 2.

FIG. 4 is an enlarged cross-sectional view illustrating portion ‘B’ in FIG. 2.

FIGS. 5, 6, 7, 8, 9, 10, 11, 12, 13, 14, 15, 16, 17, 18, 19, 20, 21 and 22 are views illustrating a method of manufacturing a semiconductor package in accordance with an example embodiment of the present inventive concept.

### DETAILED DESCRIPTION OF EXAMPLE EMBODIMENTS

Hereinafter, example embodiments of the present inventive concept will be explained in detail with reference to the accompanying drawings.

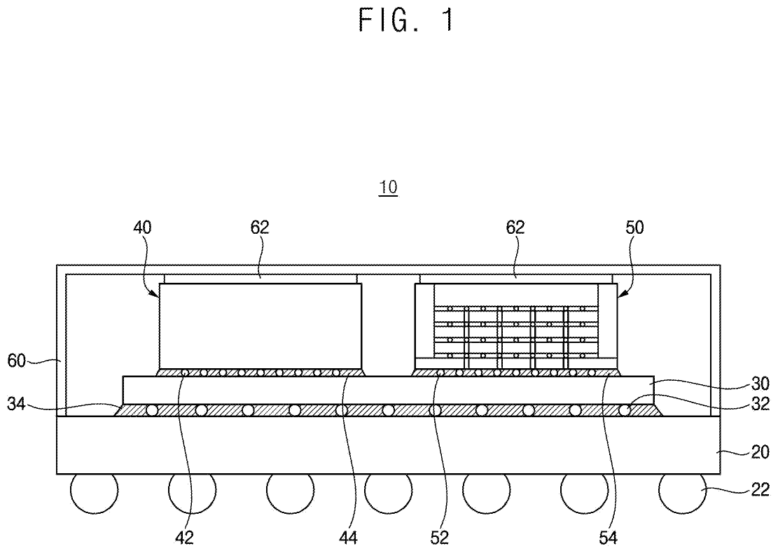

FIG. 1 is a cross-sectional view illustrating an electronic device in accordance with an example embodiment of the present inventive concept.

Referring to FIG. 1, an electronic device 10 may include a substrate 20, an interposer 30, a first semiconductor device 40 and a second semiconductor device 50. In addition, the electronic device 10 may further include first and second underfill members 34, 44 and 54, and a heat slug 60.

In an example embodiment of the present inventive concept, the electronic device 10 may be a memory module having a stacked chip structure in which a plurality of dies (chips) are stacked on each other. For example, the electronic device 10 may include a semiconductor memory device having a 2.5D chip structure. The electronic device 10 including the 2.5D chip structure memory device may include the interposer 30 for electrically connecting the first and second semiconductor devices (e.g., electronic components) 40 and 50 to each other. For example, the first and second semiconductor devices 40 and 50 may be electrically connected to the interposer 30.

In this case, the first semiconductor device 40 may include a logic semiconductor device, and the second semiconductor device 50 may include a memory device. The logic semiconductor device may be an ASIC as a host such as a CPU, GPU, or SOC. The memory device may include a high bandwidth memory (HBM) device.

In an example embodiment of the present inventive concept, the substrate 20 may be a substrate having an upper surface and a lower surface facing each other. For example, the substrate 20 may be a printed circuit board (PCB). The printed circuit board may be a multi-layer circuit board having vias and various circuits therein.

The interposer 30 may be disposed on the substrate 20. The interposer 30 may be mounted on the substrate 20 through solder bumps 32. A planar area of the interposer 30 may be smaller than a planar area of the substrate 20. When viewed from a plan view, the interposer 30 may be disposed within an area of the substrate 20.

The interposer 30 may be, for example, a silicon interposer or a redistribution wiring interposer having a plurality of wirings formed therein. The first semiconductor device 40 and the second semiconductor device 50 may be connected to each other through the wirings in the interposer 30 and/or electrically connected to the substrate 20 through the solder bumps 32. The silicon interposer may provide a high-density interconnection between the first and second semiconductor devices 40 and 50.

In an example embodiment of the present inventive concept, the first semiconductor device 40 may be disposed on the interposer 30. For example, the first semiconductor device 40 may be mounted on the interposer 30 by a flip chip bonding method. In this case, the first semiconductor device 40 may be mounted on the interposer 30 such that an active surface, of the first semiconductor device 40, on which chip pads are formed faces the interposer 30. The chip pads of the first semiconductor device 40 may be electrically connected to bonding pads of the interposer 30 by conductive bumps 42. For example, the conductive bumps may include micro bumps (uBumps).

The second semiconductor device 50 may be disposed on the interposer 30 and may be spaced apart from the first semiconductor device 40. For example, the second semiconductor device 50 may be mounted on the interposer 30 by a flip chip bonding method. In this case, bonding pads of the second semiconductor device 50 may be electrically connected to bonding pads of the interposer 30 by conductive bumps 52. For example, the conductive bumps 52 may include micro bumps (uBumps).

Although one first semiconductor device 40 and one second semiconductor device 50 are illustrated to be disposed, it will be understood that the present inventive concept is not limited thereto.

In an example embodiment of the present inventive concept, the first underfill members 44 and 54 may be underfilled between the first semiconductor device 40 and the interposer 30 and between the second semiconductor device 50 and the interposer 30, respectively. The second underfill member 34 may be underfill between the interposer 30 and the substrate 20.

The first and second underfill members 34, 44 and 54 may include a material having relatively high fluidity to fill small spaces between the first and second semiconductor devices 40 and 50 and the interposer 30 and between the interposer 30 and the substrate 20. For example, the first and second underfill members 34, 44 and 54 may include an adhesive including an epoxy material.

The second semiconductor device 50 may include a buffer die and a plurality of memory dies (chips) sequentially stacked on the buffer die. The buffer die and the memory dies may be electrically connected to each other by through silicon vias (TSVs).

In an example embodiment of the present inventive concept, the heat slug 60 may cover the substrate 20 to thermally contact the first and second semiconductor devices 40 and 50. Thermal interface materials (TIMs) 62 may be provided on upper surfaces of the first and second semiconductor devices 40 and 50, respectively. The heat slug 60 may be disposed to thermally contact the first and second semiconductor devices 40 and 50 via the thermal interface materials 62.

External connection pads may be formed on the lower surface of the substrate 20, and external connection members 22 may be disposed on the external connection pads for electrical connection with external devices. For example, the external connection member 22 may be a solder ball. The electronic device 10 may be mounted on a module board via the solder balls to form a memory module.

In an example embodiment of the present inventive concept, the second semiconductor device 50 may include the buffer die and a plurality of the memory dies (chips) sequentially stacked on the buffer die. The buffer die and the memory dies may be electrically connected to each other by through silicon vias (TSVs). The through silicon vias may be electrically connected to each other by conductive bumps. The buffer die and the memory die may communicate (e.g., transmit and receive) data signals and control signals through the through silicon vias.

The electronic device 10 may include the high bandwidth memory (HBM) or a multi-chip package to provide high performance such as high capacity and high speed operation. Accordingly, heat dissipation characteristics may be desirable for the electronic device. For example, since chips are stacked in a vertical direction in the HBM, it may be desirable to secure a heat dissipation passage in a vertical direction.

As will be described later, the second semiconductor device 50 may include first conductive bumps for signal transmission between the stacked chips and second conductive bumps for heat dissipation. Each of the second conductive bumps may include a heat dissipation pad (e.g., a thermal pad) including a material having excellent thermal conductivity and having relatively high heat dissipation. Thus, thermal efficiency and dissipation of the HBM package may be increased.

Hereinafter, the HBM package device of FIG. 1 will be described.

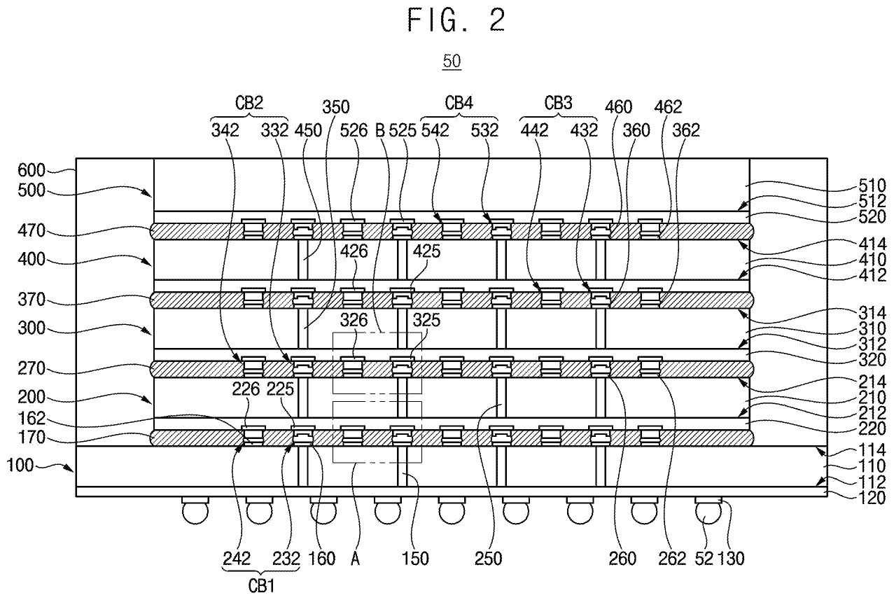

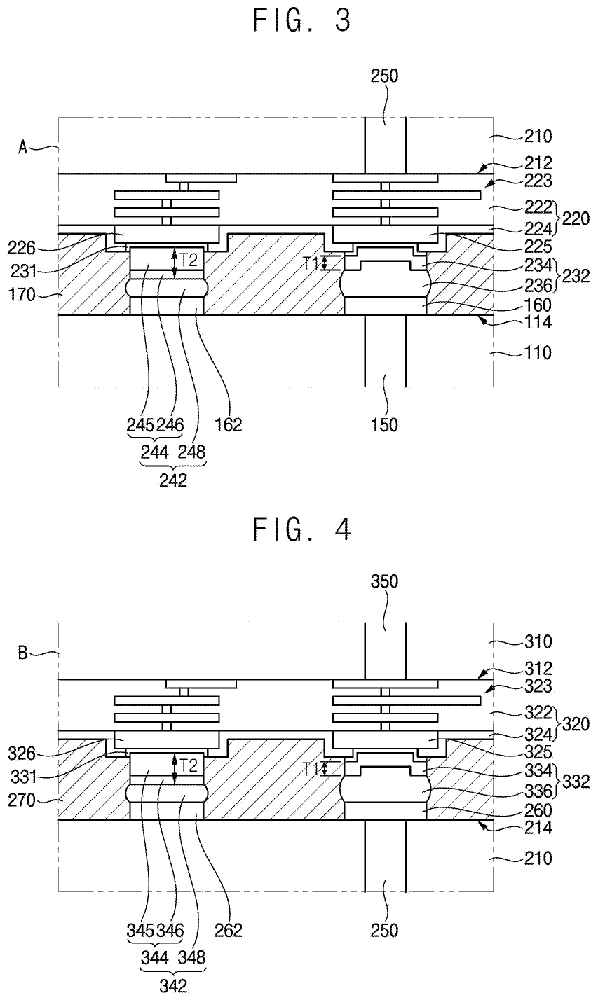

FIG. 2 is a cross-sectional view illustrating a semiconductor package in accordance with an example embodiment of the present inventive concept. FIG. 3 is an enlarged cross-sectional view illustrating portion ‘A’ in FIG. 2. FIG. 4 is an enlarged cross-sectional view illustrating portion ‘B’ in FIG. 2.

Referring to FIGS. 2 to 4, a semiconductor package 50 may include a first semiconductor chip 100 and second, third, fourth and fifth semiconductor chips 200, 300, 400 and 500 sequentially stacked on the first semiconductor chip 100, and a molding member 600 covering the second, third, fourth and fifth semiconductor chips 200, 300, 400 and 500 while disposed on the first semiconductor chip 100. In addition, the semiconductor package 50 may further include first, second, third and fourth conductive connection members CB1, CB2, CB3 and CB4 provided between the first, second, third, fourth and fifth semiconductor chips 100, 200, 300, 400 and 500. Further, the semiconductor package 50 may further include first, second, third and fourth adhesive layers 170, 270, 370 and 470 interposed between the first, second, third, fourth and fifth semiconductor chips 100, 200, 300, 400 and 500. The semiconductor package 50 may further include conductive bumps 52 that are on a lower surface of the first semiconductor chip 100.

In this embodiment, the second, third, fourth and fifth semiconductor chips 200, 300, 400 and 500 may be substantially the same as or similar to each other. Thus, same or similar reference numerals may be used to refer to the same or like elements and any repetitive explanation or description concerning the above elements may be omitted or briefly discussed.

The first, second, third, fourth and fifth semiconductor chips 100, 200, 300, 400 and 500 may be stacked on a package substrate such as a printed circuit board (PCB) or an interposer. In this embodiment, a semiconductor package as a multi-chip package is illustrated as including five stacked semiconductor chips 100, 200, 300, 400 and 500. However, the present inventive concept is not necessarily limited thereto. The semiconductor package might not be limited thereto, and for example, the semiconductor package may include 4, 8, 12, or 16 stacked semiconductor chips on the first semiconductor chip.

For example, the semiconductor package 50 may include a high bandwidth memory (HBM) device. For example, the HBM package may include a processor chip and a broadband interface for faster data exchange. The HBM package may have an input/output (TSV I/O) structure including a large number of through silicon via structures to implement a wideband interface. Processor chips that require HBM package support may include a central processing unit (CPU), a graphics processing unit (GPU), a microprocessor, a microcontroller, an application processor (AP), or an application specific integrated circuit (ASIC) chip including a digital signal processing core and an interface for signal exchange.

The semiconductor package 50 may include the first semiconductor chip 100 as a buffer die and the second, third, fourth and fifth semiconductor chips 200, 300, 400 and 500 as memory dies, sequentially stacked on each other. The first, second, third, fourth and fifth semiconductor chips 100, 200, 300, 400 and 500 may be electrically connected to each other by through electrodes such as through silicon vias (TSVs). The memory die may include a memory device, and the buffer die may include a controller controlling the memory device.

In an example embodiment of the present inventive concept, the first semiconductor chip 100 may include a first substrate 110, a first wiring layer 120, first through electrodes 150, first bonding pads 130, and first signal bonding pads 160 and first dummy bonding pads 162. The first wiring layer 120 may be provided on a first surface 112 of a first substrate 110, and the first through electrodes 150 may penetrate the first substrate 110. The first bonding pads 130 may be provided on the first wiring layer 120, and the first signal bonding pads 160 and first dummy bonding pads 162, which may be referred to as second bonding pads, may be provided on a second surface 114 of the first substrate 110. In addition, the first semiconductor chip 100 may further include conductive bumps 52 respectively provided on the first bonding pads 130. The first semiconductor chip 100 may be mounted on the interposer 30 of FIG. 1 via the conductive bumps 52. For example, the conductive bumps 52 may include solder bumps.

The first substrate 110 may have the first surface 112 and the second surface 114 opposite to the first surface 112. The first surface 112 may be an active surface, and the second surface 114 may be an inactive surface. Circuit patterns and cells may be formed on the first surface 112 of the first substrate 110. For example, the first substrate 110 may be a single crystal silicon substrate. The circuit patterns may include transistors, capacitors, diodes, etc. The circuit patterns may constitute circuit elements. Accordingly, the first semiconductor chip 100 may be a semiconductor device in which a plurality of the circuit elements are formed.

The first wiring layer 120 may be provided on the first surface 112 of the first substrate 110, that is, an active surface. For example, the first wiring layer 120 may include a plurality of insulating layers and upper wirings within the insulating layers. Additionally, chip pads may be provided in the outermost insulating layer of the first wiring layer 120, and the first bonding pads 130 may be provided on the chip pads.

The first through electrodes (through silicon vias, TSVs) 150 may be provided to vertically penetrate the first substrate 110 from the first surface 112 to the second surface 114 of the first substrate 110. A first end portion of the first through electrode 150 may contact the upper wiring of the first wiring layer. However, the present inventive concept is not necessarily limited thereto, and for example, the first through electrode 150 may penetrate the first wiring layer and directly contact the first bonding pad 130.

A first backside insulating layer may be provided on the second surface 114 of the first substrate 110, that is, a backside surface. The second bonding pads may be provided on the first backside insulating layer. The first signal bonding pad 160 may be disposed on a surface of the first through electrode 150 that is exposed from the second surface 114 of the first substrate 110. Accordingly, the first signal bonding pad 160 may be electrically connected to the first through electrode 150. In addition, the first dummy bonding pad 162 may be electrically insulated from the first through electrode 150. The first signal bonding pads 160 and the first dummy bonding pads 162 may include a same metal material as each other, such as nickel (Ni).

In an example embodiment of the present inventive concept, the second semiconductor chip 200 may include a second substrate 210, a second wiring layer 220, second signal chip pads 225 and second dummy chip pads 226 as third bonding pads, second through electrodes 250, and second signal bonding pads 260 and second dummy bonding pads 262 as fourth bonding pads. In addition, the second semiconductor chip 200 may further include first conductive connection members CB1 respectively provided on the third bonding pads.

For example, the second substrate 210 may have a first surface 212 and a second surface 214 opposite to the first surface 212. The first surface 212 may be an active surface, and the second surface 214 may be an inactive surface. Circuit elements may be formed on the first surface 212 of the second substrate 210. The circuit elements may include a plurality of memory devices. Examples of the memory device may include a volatile semiconductor memory device and a non-volatile semiconductor memory device. An insulation interlayer may be formed on the first surface 212 of the second substrate 210 to cover the circuit elements. As illustrated in FIG. 3, the second wiring layer 220 may include a metal wiring layer 222 and a protective layer 224 sequentially stacked on the first surface 212 of the second substrate 210. The metal wiring layer 222 may include a plurality of insulating layers, upper wirings 223 within the insulating layers, and the second signal chip pads 225 and the second dummy chip pads 226 as uppermost wirings. The protective layer 224 may be formed on the metal wiring layer 222 and may expose at least portions of the second signal chip pads 225 and the second dummy chip pads 226.

The second signal chip pads 225 may be electrically connected to the circuit elements through the upper wirings 223 and contact plugs that are disposed in the insulation interlayer. The second signal chip pad 225 may be electrically connected to the second through electrode 250 through the upper wiring 223. The second dummy chip pad 226 may be electrically insulated from the second through electrode 250.

A second backside insulating layer may be provided on the second surface 214 of the second substrate 210. The fourth bonding pads may be provided on the second backside insulating layer. The second signal bonding pad 260 may be disposed on an exposed surface of the second through electrode 250. Accordingly, the second signal bonding pad 260 may be electrically connected to the second through electrode 250. In addition, the second dummy bonding pad 262 may be electrically insulated from the second through electrode 250. The second signal bonding pads 260 and the second dummy bonding pads 262 may include a same metal material as each other such as nickel (Ni).

In an example embodiment of the present inventive concept, the second semiconductor chip 200 may be stacked on the first semiconductor chip 100 via the first conductive connection members CB1. The first conductive connection members CB1 include first conductive bumps 232, which are formed on the second signal chip pads 225, and second conductive bumps 242, which are formed on the second dummy chip pads 226.

Each of the first conductive bumps 232 may include a signal bump pad 234 and a first solder bump 236. The signal bump pad 234 may be provided on the second signal chip pad 225 and may have a dimple (e.g., a groove or an indentation) 235 thereon. The first solder bump 236 may be provided on the signal bump pad 234. Each of the second conductive bumps 242 may include a thermal bump pad 244 and second solder bumps 248. The thermal bump pad 244 may be provided on the second dummy chip pad 226 and may have a flat upper surface. The second solder bumps 248 may be provided on the thermal bump pad 244. The thermal bump pad 244 may include a first plating pad 245 and a second plating pad 246 provided on the first plating pad 245.

For example, the signal bump pad 234 may have a first thickness T1 within a range of about 1 μm to about 5 μm. The signal bump pad 234 may include a metal material such as nickel (Ni). The signal bump pad 234 may include a metal material having a first thermal conductivity. The thermal bump pad 244 may have a second thickness T2 within a range of about 3 μm to about 7 μm. The thermal bump pad 244 may include a metal material having a second thermal conductivity greater than the first thermal conductivity. The first plating pad 245 may include copper (Cu), and the second plating pad 246 may include nickel (Ni). The signal bump pad 234 and the thermal bump pad 244 may have a diameter within a range of about 10 μm to about 20 μm. The first and second solder bumps 236 and 248 may include, for example, tin (Sn), tin/silver (Sn/Ag), tin/copper (Sn/Cu), tin/indium (Sn/In), tin/silver/copper (Sn/Ag/Cu), etc.

The first conductive bump 232 for signal transmission may include the dimple-shaped bump pad 234, and the second conductive bump 242 for heat dissipation may include the dome-shaped bump pad 244. Nickel included in the signal bump pad 234 may have a thermal conductivity of about 60 W/mK, and copper included in the thermal bump pad 244 may have a thermal conductivity of about 400 W/mK. An occupying ratio of the second conductive bumps 242 may be at least about 70% of the total first conductive connection pads and may have relatively high thermal conductivity, thereby reducing vertical thermal resistance and improving heat dissipation characteristics.

In an example embodiment of the present inventive concept, the first adhesive layer 170 may be provided to fill a space between the first conductive connection members CB1 and a space between the first semiconductor chip 100 and the second semiconductor chip 200. For example, the first adhesive layer may include a non-conductive film (NCF).

For example, the second semiconductor chip 200 and the first semiconductor chip 100 may be attached to each other by a thermal compression process using the non-conductive film. In the thermal compression process, the non-conductive film may be liquefied and may have fluidity, may flow between the second semiconductor chip 200 and the first wafer W1 and between the first conductive connection members CB1, and then may cured to fill the space between the first conductive connection members CB1. A portion of the cured first adhesive layer 170 may protrude beyond a side surface of the second semiconductor chip 200.

In an example embodiment of the present inventive concept, the third semiconductor chip 300 may include a third substrate 310, a third wiring layer 320, third signal chip pads 325 and third dummy chip pads 326 as fifth bonding pads, third through electrodes 350, and third signal bonding pads 360 and third dummy bonding pads 362 as sixth bonding pads. In addition, the third semiconductor chip 300 may further include second conductive connection members CB2 respectively provided on the fifth bonding pads.

As illustrated in FIG. 4, the third wiring layer 320 may include a metal wiring layer 322 and a protective layer 324 sequentially stacked on a first surface 312 of the third substrate 310. The metal wiring layer 322 may include a plurality of insulating layers, upper wirings 323 within the insulating layers, and the third signal chip pads 325 and the third dummy chip pads 326 as uppermost wirings. The protective layer 324 may be formed on the metal wiring layer 322 and may expose at least a portion of the third signal chip pads 325 and at least a portion of the third dummy chip pads 326.

The third signal chip pads 325 may be electrically connected to circuit elements through the upper wirings 323 and contact plugs in an insulation interlayer. The third signal chip pad 325 may be electrically connected to the third through electrode 350 through the upper wiring 323. The third dummy chip pad 326 may be electrically insulated from the third through electrode 350.

A third backside insulating layer may be provided on a second surface 314 of the third substrate 310. The sixth bonding pads may be provided on the third backside insulating layer. The third signal bonding pad 360 may be disposed on an exposed surface of the third through electrode 350. Accordingly, the third signal bonding pad 360 may be electrically connected to the third through electrode 350. In addition, the third dummy bonding pad 362 may be electrically insulated from the third through electrode 350. The third signal bonding pads 360 and the third dummy bonding pads 362 may include a same metal material as each other such as nickel (Ni).

In an example embodiment of the present inventive concept, the third semiconductor chip 300 may be stacked on the second semiconductor chip 200 via the second conductive connection members CB2. The second conductive connection members CB2 may include first conductive bumps 332, which are formed on the third signal chip pads 325, and second conductive bumps 343, which are formed on the third dummy chip pads 326.

Each of the first conductive bumps 332 may include a signal bump pad 334 and a first solder bump 336. The signal bump pad 334 may be provided on the third signal chip pad 325 and may have a dimple 335 thereon. The first solder bump may be provided on the signal bump pad 334. Each of the second conductive bumps 342 may include a thermal bump pad 344 and a second solder bump 348. The thermal bump pad 344 may be provided on the third dummy chip pad 326 and may have a flat upper surface. The second solder bump 348 may be provided on the thermal bump pad 344. The thermal bump pad 344 may include a first plating pad 345 and a second plating pad 346 provided on the first plating pad 345.

For example, the signal bump pad 334 may have a first thickness T1 within a range of about 1 μm to about 5 μm. The signal bump pad 334 may include a metal material such as nickel (Ni). The signal bump pad 334 may include a metal material having a first thermal conductivity. The thermal bump pad 344 may have a second thickness T2 within a range of about 3 μm to about 7 μm. The thermal bump pad 344 may include a metal material having a second thermal conductivity greater than the first thermal conductivity. The first plating pad 345 may include, for example, copper (Cu), and the second plating pad 346 may include, for example, nickel (Ni). The signal bump pad 334 and the thermal bump pad 344 may have a diameter within a range of about 10 μm to about 20 μm.

The first conductive bump 332 for signal transmission may include the dimple-shaped bump pad 334, and the second conductive bump 342 for heat dissipation may include the dome-shaped bump pad 344. Nickel included in the signal bump pad 334 may have a thermal conductivity of about 60 W/mK, and copper included in the thermal bump pad 344 may have a thermal conductivity of about 400 W/mK. An occupying ratio of the second conductive bumps 342 is at least about 70% of the total second conductive connection pads and may have relatively high thermal conductivity, thereby reducing vertical thermal resistance and improving heat dissipation characteristics.

In addition, the second adhesive layer 270 may be provided to fill a space between the second conductive connection members CB2 and a space between the second semiconductor chip 200 and the third semiconductor chip 300.

In an example embodiment of the present inventive concept, the fourth semiconductor chip 400 may be stacked on the third semiconductor chip 300 via the third conductive connection members CB3. The third conductive connection members CB3 may include first conductive bumps 432, which are formed on fourth signal chip pads 425, and second conductive bumps 442, which are formed on fourth dummy chip pads 426.

The first conductive bump 432 for signal transmission may include a dimple-shaped bump pad, and the second conductive bump 442 for heat dissipation may include a dome-shaped bump pad. An occupying ratio of the second conductive bumps 442 may be at least about 70% or more of the total third conductive connection pads and may have relatively high thermal conductivity, thereby reducing vertical thermal resistance and improving heat dissipation characteristics.

In addition, the third adhesive layer 370 may be provided to fill a space between the third conductive connection members CB3 and a space between the third semiconductor chip 300 and the fourth semiconductor chip 400.

In an example embodiment of the present inventive concept, the fifth semiconductor chip 500 may be stacked on the fourth semiconductor chip 400 via the fourth conductive connection members CB4. The fourth conductive connection members CB4 may include first conductive bumps 532, which are formed on fifth signal chip pads 525, and second conductive bumps 543, which are formed on fifth dummy chip pads 526.

The first conductive bump 532 for signal transmission may include a dimple-shaped bump pad, and the second conductive bump 542 for heat dissipation may include a dome-shaped bump pad. An occupying ratio of the second conductive bumps 542 may be at least about 70% of the total fourth conductive connection pads and may have relatively high thermal conductivity, thereby reducing vertical thermal resistance and improving heat dissipation characteristics.

In addition, the fourth adhesive layer 470 may be provided to fill a space between the fourth conductive connection members CB4 and a space between the fourth semiconductor chip 400 and the fifth semiconductor chip 500.

As mentioned above, the semiconductor package 50 may include the second, third, fourth and fifth semiconductor chips 200, 300, 400 and 500 sequentially stacked on the first semiconductor chip 100 via the first, second, third and fourth conductive connection members CB1, CB2, CB3 and CB4. The first, second, third and fourth conductive connection members CB1, CB2, CB3 and CB4 may include the corresponding first conductive bumps 232, 332, 432 and 532, which are disposed on the respective signal chip pads 225, 325, 425 and 525 of the second, third, fourth and fifth semiconductor chips 200, 300, 400 and 500, and the corresponding second conductive bumps 242, 342, 442 and 542, which are disposed on the respective dummy chip pads 226, 326, 426 and 526 of the second, third, fourth and fifth semiconductor chips 200, 300, 400 and 500.

Each of the first conductive bumps 232, 332, 432 and 532 may include the signal bump pad 234 and 334, which has the dimple shape thereon, and the first solder bump 236, which is provided on the signal bump pad 234 and 334. Each of the second conductive bumps 242, 342, 442 and 542 may include the thermal bump pad 244 and 344, which has the flat upper surface, and the second solder bump 248 and 348, which is provided on the thermal bump pad 244 and 344.

For example, the first conductive bump 232, 332, 432 and 532 for signal transmission may include the dimple-shaped bump pad (e.g., 234 and 334), and the second conductive bump 242, 342, 442 and 542 for heat dissipation may include the dome-shaped bump pad. For example, the second conductive bump 242, 342, 442 and 542 may have a polygonal shape, such as a rectangular shape, from a cross-sectional view. Since the second conductive bumps 242, 342, 442 and 542 have relatively high thermal conductivity, it may be possible to improve heat dissipation characteristics by reducing vertical thermal resistance.

Hereinafter, a method of manufacturing the semiconductor package of FIG. 1 will be described.

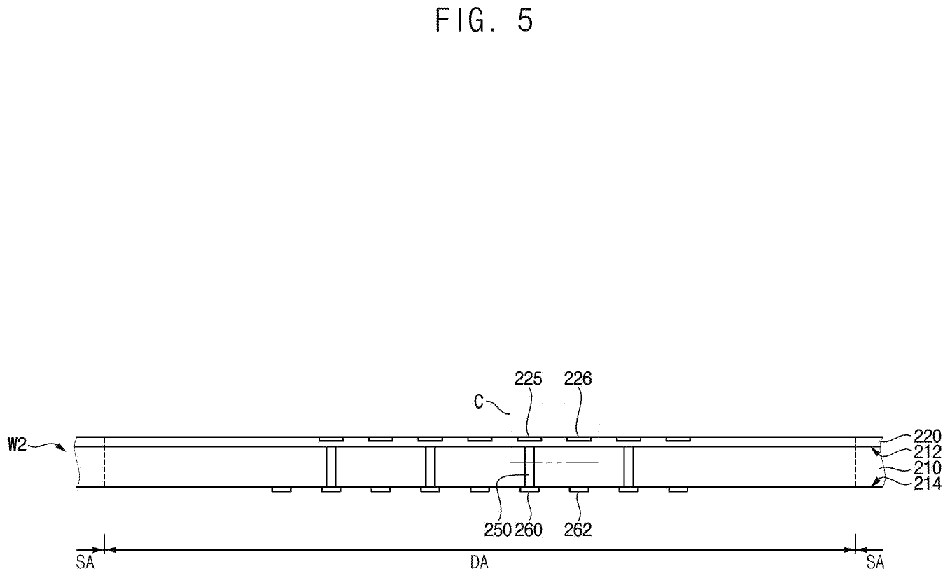

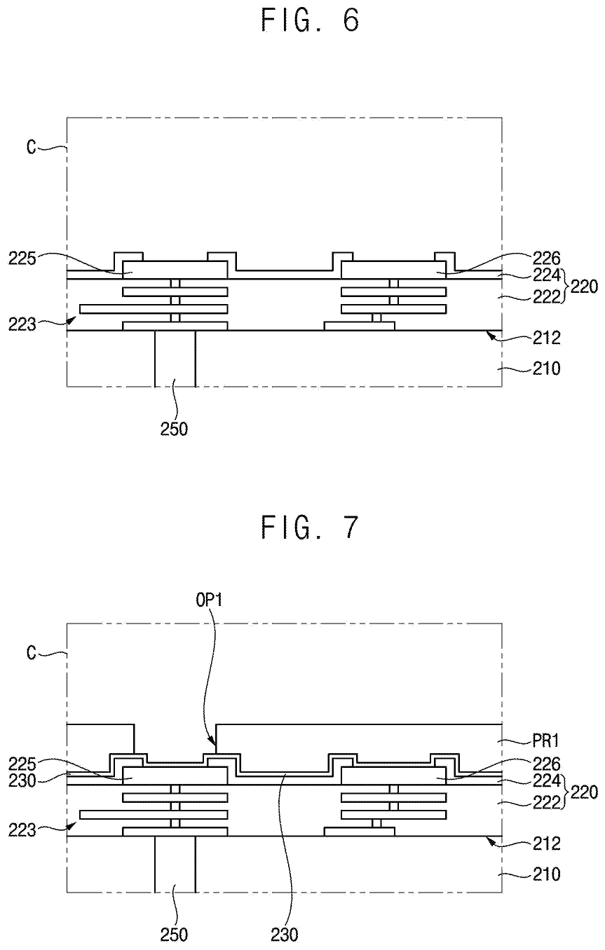

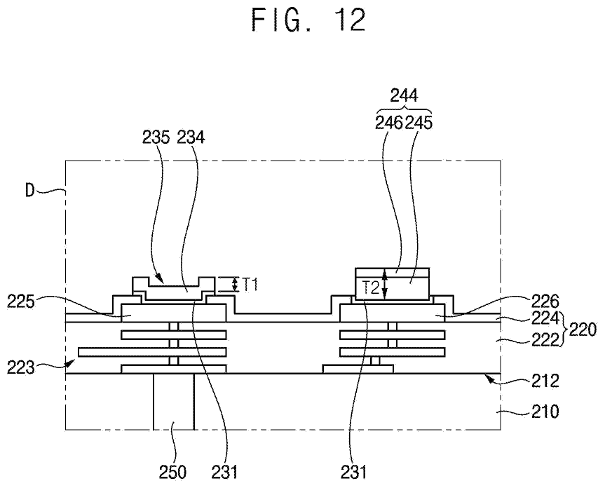

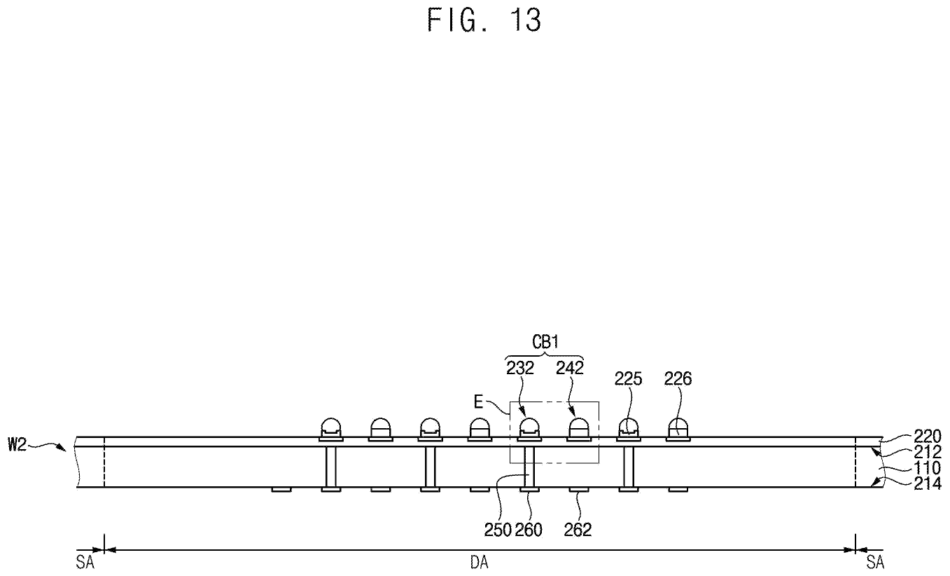

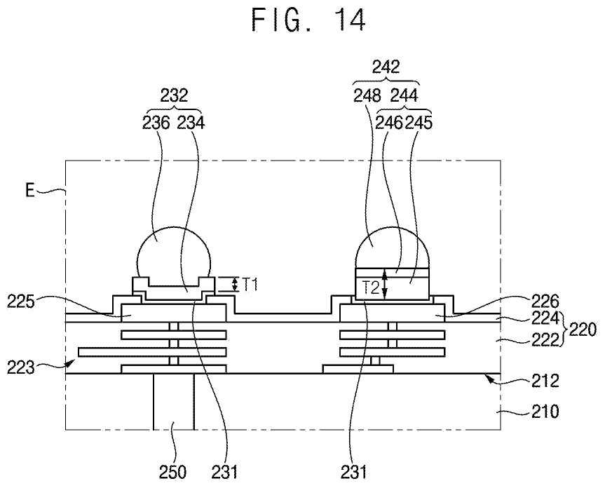

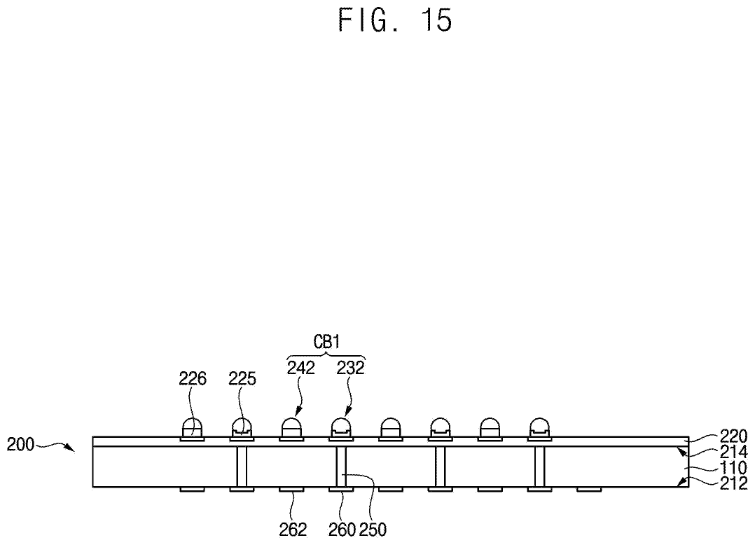

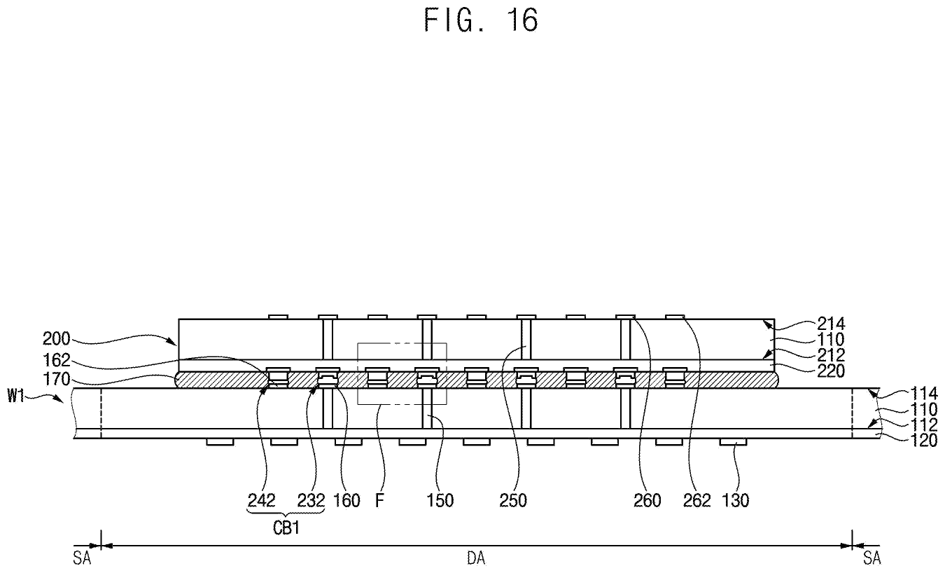

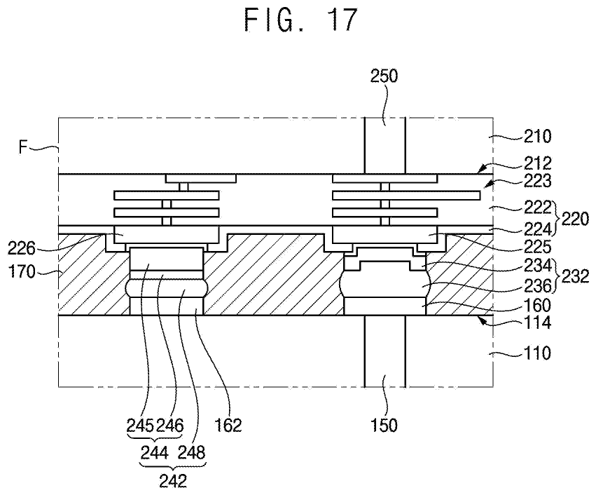

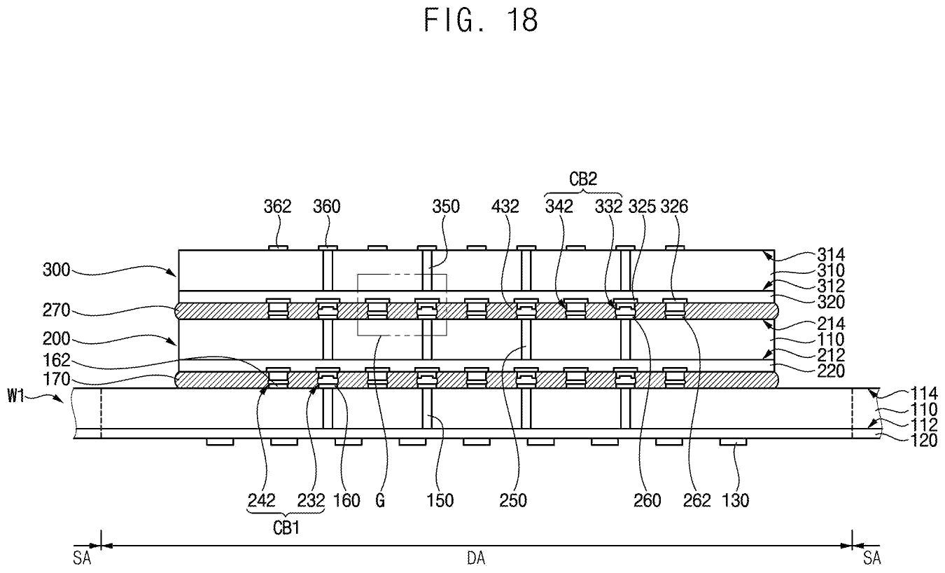

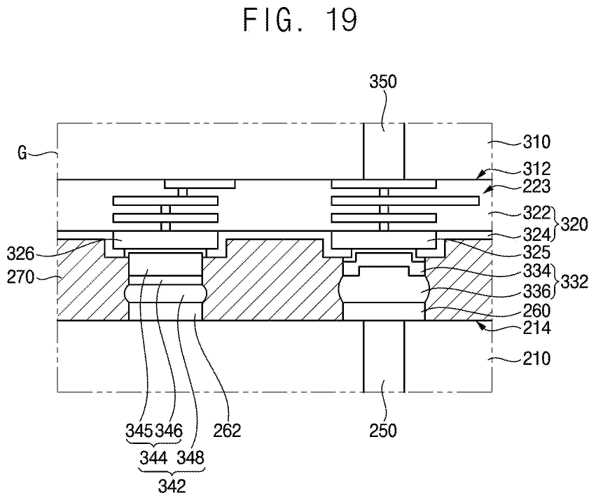

FIGS. 5 to 22 are views illustrating a method of manufacturing a semiconductor package in accordance with an example embodiment of the present inventive concept. FIGS. 6 to 10 are enlarged cross-sectional views illustrating portion ‘C’ in FIG. 4. FIG. 12 is an enlarged cross-sectional view illustrating portion ‘D’ in FIG. 11. FIG. 14 is an enlarged cross-sectional view illustrating portion ‘E’ in FIG. 13. FIG. 17 is an enlarged cross-sectional view illustrating portion ‘F’ in FIG. 16. FIG. 19 is an enlarged cross-sectional view illustrating portion ‘G’ in FIG. 18.

Referring to FIGS. 5 and 6, a second wafer W2 in which a plurality of second semiconductor chips (e.g., dies) are formed may be provided.

In an example embodiment of the present inventive concept, the second wafer W2 may include a second substrate 210 having a first surface 212 and a second surface 214 opposite to the first surface 212. The second wafer W2 may include a die region DA and a scribe lane region SA at least partially surrounding the die region DA. The second wafer W2 may be cut along the scribe lane region SA that divides a plurality of the die regions DA of the second wafer W2. The cutting along the scribe lane region SA may be performed with a sawing process so that the die regions DA can be individualized into a plurality of second semiconductor chips.

Circuit elements may be formed in the die region DA on the first surface 212 of the second substrate 210. The circuit element may include a plurality of memory devices. Examples of the memory device may include a volatile semiconductor memory device and a non-volatile semiconductor memory device. Examples of the volatile semiconductor memory device may be DRAM, SRAM, etc. Examples of the non-volatile semiconductor memory device may be EPROM, EEPROM, Flash EEPROM, etc.

For example, the second substrate 210 may include silicon, germanium, silicon-germanium, or III-V compounds, e.g., GaP, GaAs, GaSb, etc. In some embodiments of the present inventive concept, the second substrate 210 may be a silicon-on-insulator (SOI) substrate, or a germanium-on-insulator (GOI) substrate.

The circuit elements may include, for example, transistors, capacitors, wiring structures, etc. The circuit elements may be formed on the first surface 212 of the second substrate 210 by performing a fab process called a front-end-of-line (FEOL) process for manufacturing semiconductor devices. A surface of the second substrate 210 on which the FEOL process is performed may be referred to as a front side surface of the second substrate 210, and a surface opposite to the front side surface may be referred to as a backside surface. An insulation interlayer may be formed on the first surface 212 of the second substrate 210 to cover the circuit elements.

In an example embodiment of the present inventive concept, the second wafer W2 may include a second wiring layer 220 that is provided on the first surface 212 of the second substrate 210. The second wiring layer 220 may include a metal wiring layer 222 and a protective layer 224 sequentially stacked on the second substrate 210. The second wiring layer 220 may be formed by performing a wiring process called a back-end-of-line (BEOL) process.

The metal wiring layer 222 may include a plurality of insulating layers, upper wirings 223 within the plurality of insulating layers, and second signal chip pads 225 and second dummy chip pads 226 as uppermost wirings. The protective layer 224 may be formed on the metal wiring layer 222 and may cover the second signal chip pads 225 and the second dummy chip pads 226. For example, the protective layer 224 may expose a portion of each of the second signal chip pads 225 and a portion of each of the second dummy chip pads 226.

For example, the insulating layers may be formed to include an oxide such as silicon oxide, carbon-doped oxide, or fluorine-doped oxide. The protective layer 224 may include, for example, a passivation layer including a nitride such as silicon nitride (SiN). Additionally, the passivation layer may include, for example, an organic passivation layer, which includes an oxide layer, and an inorganic passivation layer, which includes a nitride layer, sequentially stacked. The upper wirings, the second signal chip pads 225, and the second dummy chip pads 226 may include a metal material such as aluminum (Al) or copper (Cu).

In an example embodiment of the present inventive concept, the second wafer W2 may include second through electrodes 250 and fourth bonding pads 260 and 262. The second through electrodes 250 may penetrate the second substrate 210. The fourth bonding pads 260 and 262 may be provided on the second surface 214 of the second substrate 210. The fourth bonding pads 260 and 262 may include second signal bonding pads 260 and second dummy bonding pads 262.

The second through electrode 250 may be provided to vertically penetrate the second substrate 210 from the first surface 212 to the second surface 214 of the second substrate 210. A first end portion of the second through electrode 250 may contact the upper wiring of the metal wiring layer 222. However, the present inventive concept is not necessarily limited thereto, and for example, the second through electrode 250 may penetrate the metal wiring layer 222 and directly contact the second signal chip pad 225.

A second backside insulating layer may be provided on the second surface 214 of the second substrate 210, that is, on the backside surface. The fourth bonding pads 260 and 262 may be provided in the second backside insulating layer. The second signal bonding pad 260 may be disposed on a surface of the second through electrode 250 that is exposed from the second surface 214 of the second substrate 210. Accordingly, the second signal bonding pad 260 may be electrically connected to the second through electrode 250. In addition, the second dummy bonding pad 262 may be electrically insulated from the second through electrode 250. The second signal bonding pads 260 and the second dummy bonding pads 262 may include a same metal material as each other such as nickel (Ni).

In an example embodiment of the present inventive concept, the second signal chip pads 225 may be electrically connected to the circuit elements through the upper wirings 223 and contact plugs in the insulation interlayer. The second signal chip pad 225 may be electrically connected to the second through electrode 250 through the upper wiring 223. The second dummy chip pad 226 may be electrically insulated from the second through electrode 250. The numbers, sizes, arrangements, etc. of the insulating layers, the upper wirings, the chip pads, the through electrodes and the bonding pads of the second wiring layer may be provided as examples, and it may be understood that the present inventive concept is not limited thereto.

Referring to FIGS. 7 to 14, first conductive bumps 232 may be formed on the second signal chip pads 225 on the second wiring layer 220, respectively, and second conductive bumps 242 may be formed on the second dummy chip pads 226, respectively.

As illustrated in FIG. 7, a seed layer 230 may be formed on the second protective layer 224, and a photoresist pattern PR1 having a first opening OP1 that exposes a first conductive bump region may be formed on the second protective layer 224.

The seed layer 230 may include, for example, titanium/copper (Ti/Cu), nickel/gold (Ni/Au), titanium/palladium (Ti/Pd), titanium/nickel (Ti/Ni), chrome/copper (Cr/Cu) or an alloy thereof. The seed layer 230 may be formed by a sputtering process.

After a photoresist layer is formed on the first surface 212 of the second substrate 210, an exposure process may be performed on the photoresist layer to form the first photoresist pattern PR1 having the first opening OP1 that exposes the first conductive bump region on the second signal chip pad 225.

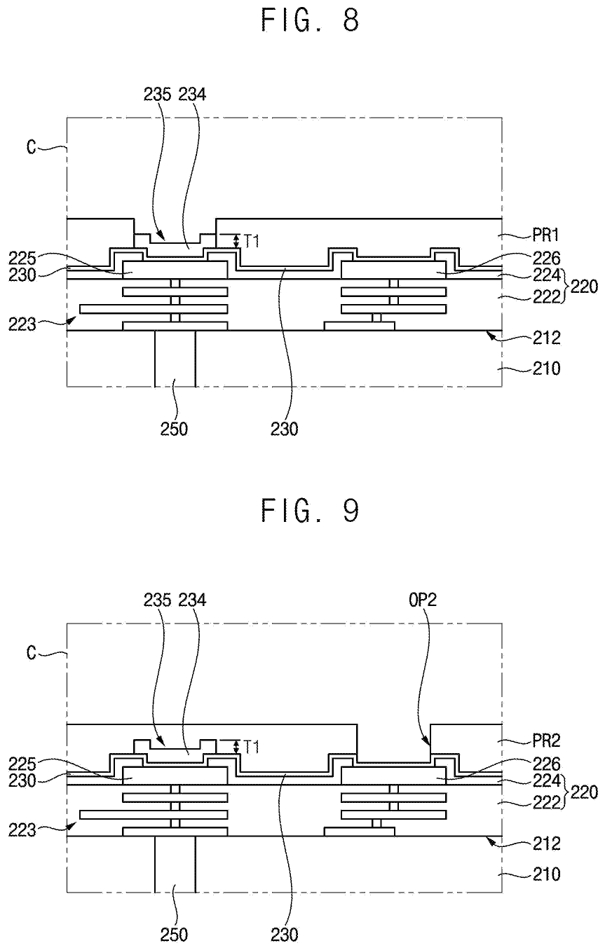

As illustrated in FIG. 8, a signal bump pad 234 may be formed on the seed layer 230 and in the first opening OP1 of the first photoresist pattern PR1. For example, the signal pump pad 234 may be formed by an electro plating process. Since the seed layer 230 is conformally formed on a portion of the second protective layer 224, which is on the second signal chip pad 225, and a portion of the second signal chip pad 225 that is exposed by the second protective layer 224, the signal bump pad 234 may have a dimple 235 in an upper portion thereof. A diameter of the dimple 235 may be substantially the same as or smaller than a diameter of the portion of the second signal chip pad 225 that is exposed by the second protective layer 224. A depth of the dimple 235 may be substantially the same as or smaller than a thickness of the second protective layer 224 that is on the second signal chip pad 225. For example, the signal bump pad 234 may have a first thickness T1 within a range of about 1 μm to about 5 μm. The signal bump pad 234 may have a diameter within a range of about 10 μm to about 20 μm. The signal bump pad 234 may include, for example, copper (Cu), aluminum (Al), tungsten, nickel (Ni), molybdenum (Mo), gold (Au), silver (Ag), chromium (Cr), tin (Sn), titanium (Ti), etc. In this embodiment of the present inventive concept, the signal bump pad 234 may include a metal material such as nickel (Ni).

As illustrated in FIG. 9, the first photoresist pattern PR1 may be removed from the second wafer W2 by a strip process and a second photoresist pattern PR2 having a second opening OP2 that exposes a second conductive bump region (e.g., a portion of the second dummy chip pad 226) may be formed on the second protective layer 224.

After a photoresist layer is formed on the first surface 212 of the second substrate 210, an exposure process may be performed on the photoresist layer to form the second photoresist pattern PR2 having the second opening OP2 that exposes the second conductive bump region on the second dummy chip pad 226.

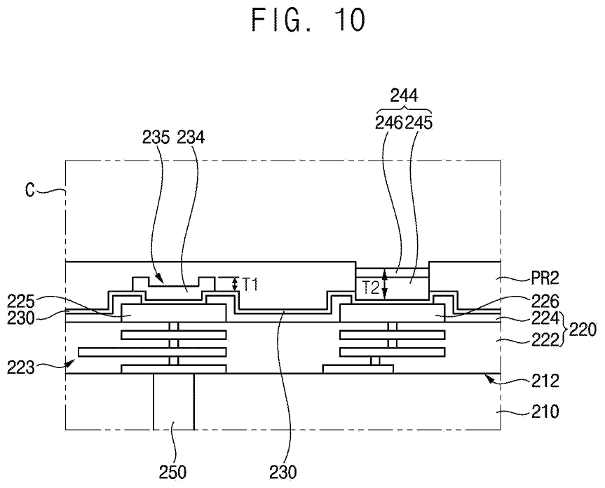

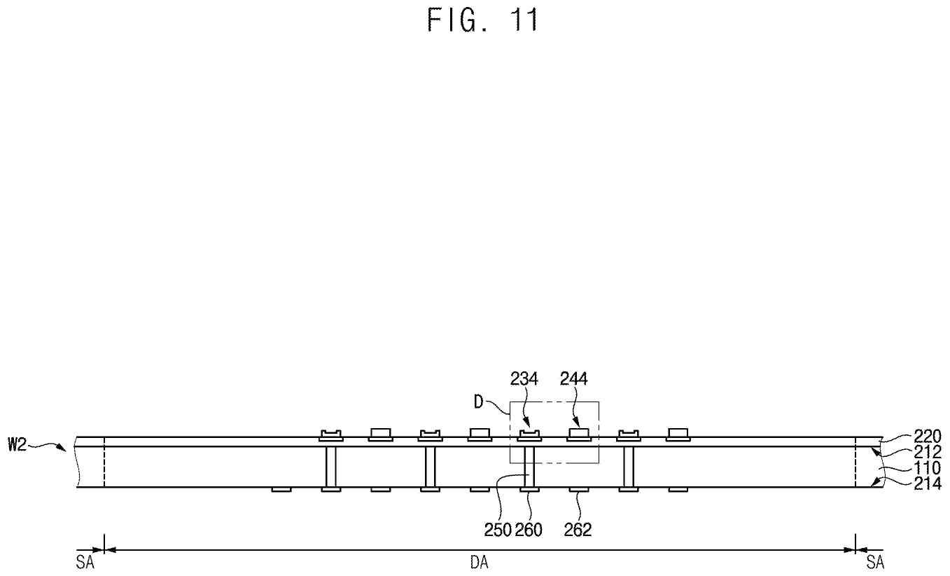

As illustrated in FIG. 10, a thermal bump pad 244 may be formed on the seed layer 230 in the second opening OP2 of the second photoresist pattern PR2. For example, the thermal bump pads 244 may be formed by an electro plating process. The thermal bump pad 244 may be formed to have a flat upper surface.

In an example embodiment of the present inventive concept, the thermal bump pad 244 may include a first plating pad 245 and a second plating pad 246 provided on the first plating pad 245. The first and second plating pads 245 and 246 may be respectively formed by electro plating processes. For example, the thermal bump pad 244 may have a second thickness T2 within a range of about 3 μm to about 7 μm. The thermal bump pad 244 may have a diameter within a range of about 10 μm to about 20 μm. The first plating pad 245 may include, for example, copper (Cu), and the second plating pad 246 may include, for example, nickel (Ni).

As illustrated in FIGS. 11 and 12, the second photoresist pattern PR2 may be removed from the second wafer W2 by a strip process, and a portion of the seed layer 230, which is exposed by the signal bump pads 234 and the thermal bump pads 244, may be removed to form a seed layer pattern 231. For example, the seed layer pattern 231 may be formed by an anisotropic etching process using the signal bump pads 234 and the thermal bump pads 244 as etching masks.

Accordingly, the signal bump pad 234 having the dimple 235 may be formed on the second signal chip pad 225, and the thermal bump pad 244 having the flat top surface may be formed on the second dummy chip pad 226.

Referring to FIGS. 13 and 14, first solder bumps 236 may be formed on the signal bump pads 234, and second solder bumps 248 may be formed on the thermal bump pads 244.

For example, a photoresist pattern having openings that expose a first conductive bump region and a second conductive bump region respectively may be formed on the second wiring layer 220 that is on the first surface 212 of the second substrate 210 In addition, the openings of the photoresist pattern may be filled up with a conductive material, and the photoresist pattern may be removed and a reflow process may be performed to form the first and second solder bumps 236 and 248, respectively. For example, the conductive material may be formed by a plating process. In addition, the first and second solder bumps may be formed by a screen printing method, a deposition method, etc.

The first and second solder bumps 236 and 248 may include, for example, tin (Sn), tin/silver (Sn/Ag), tin/copper (Sn/Cu), tin/indium (Sn/In), tin/silver/copper (Sn/Ag/Cu), etc.

Thus, first conductive connection members CB1 may be formed on second chip pads 225 and 226 that are on the first surface 212 of the second substrate 210 of the second wafer W2. The first conductive connection members CB1 may include the first conductive bumps 232, which are formed on the second signal chip pads 225, and the second conductive bumps 242, which are formed on the second dummy chip pads 226.

Each of the first conductive bumps 232 may include the signal bump pad 234 and a first solder bump 236. The signal bump pad 234 may be provided on the second signal chip pad 225 and may have the dimple 235 thereon. The first solder bump 236 may be provided on the signal bump pad 234. Each of the second conductive bumps 242 may include the thermal bump pad 244 and the second solder bump 248. The thermal bump pad 244 may be provided on the second dummy chip pad 226 and may have the flat upper surface. The second solder bump 248 may be provided on the thermal bump pad 244.

Referring to FIG. 15, the second wafer W2 may be cut along the scribe lane region SA to form an individualized second semiconductor chip 200. The second wafer W2 may be cut by a sawing process.

Referring to FIGS. 16 and 17, the second semiconductor chip 200 may be stacked on a first wafer W1. The second semiconductor chip 200 may be stacked on the first wafer W1 via the first conductive connection members CB1.

In an example embodiment of the present inventive concept, a first adhesive layer 170 may be attached to the second semiconductor chip 200 to adhere the second semiconductor chip 200 to the first wafer W1. The first adhesive layer 170 may be formed on the second wiring layer 220 to cover the first conductive connection members CB1.

For example, the first adhesive layer 170 may include a thermosetting resin. The first adhesive layer 170 may include, for example, a non-conductive film (NCF).

In some embodiments of the present inventive concept, before performing the sawing process, the first adhesive layer 170 may be formed on the second wiring layer 220 of the second wafer W2.

Then, the first wafer W1 in which a plurality of first semiconductor chips (e.g., dies) are formed may be provided.

In some example embodiments of the present inventive concept, the first wafer W1 may include a first substrate 110 having a first surface 112 and a second surface 114 opposite to the first surface 112. The first wafer W1 may include a die region DA and a scribe lane region SA at least partially surrounding the die region DA. The first wafer W1 may be cut along the scribe lane region SA that divides a plurality of the die regions DA of the first wafer W1. The cutting along the scribe lane region SA may be performed with a sawing process so that the die regions DA can be individualized into a plurality of first semiconductor chips.

Circuit elements may be formed in the die region DA on the first surface 112 of the first substrate 110. For example, the first semiconductor chip may be a logic chip including a logic circuit. The logic chip may be a controller that controls memory elements of the second semiconductor chip. The first semiconductor chip may be a processor chip such as an ASIC or an application processor (AP) serving as a host such as a CPU, GPU, or SOC.

The circuit elements may include, for example, transistors, capacitors, wiring structures, etc. The circuit elements may be formed on the first surface 112 of the first substrate 110 by performing a fab process called a front-end-of-line (FEOL) process for manufacturing semiconductor devices. A surface of the first substrate 110 on which the FEOL process is performed may be referred to as a front side surface of the first substrate, and a surface opposite to the front side surface may be referred to as a backside surface. An insulation interlayer may be formed on the first surface 112 of the first substrate 110 to cover the circuit elements.

The first wafer W may include a first wiring layer 120, first bonding pads 130, first through electrodes 150, and first signal bonding pads 160 and first dummy bonding pads 162. The first wiring layer 120 may be provided on the first surface 112 of the first substrate 110, and the first bonding pads 130 may be provided on the first wiring layer 120. The first through electrodes 150 may penetrate the first substrate 110. The first signal bonding pads 160 and the first dummy bonding pads 162, which may be referred to as second bonding pads, may be provided on the second surface 114 of the first substrate 110. The first signal bonding pad 160 may be electrically connected to the first through electrode 150. In addition, the first dummy bonding pad 162 may be electrically insulated from the first through electrode 150. The first signal bonding pads 160 and the first dummy bonding pads 162 may include a same metal material as each other such as nickel (Ni).

Then, the second semiconductor chip 200 may be stacked on the first wafer W1 by using a substrate support system WSS. The second semiconductor chips 200 may be disposed on the first wafer W1 to correspond to the die regions DA, respectively. The second semiconductor chip 200 may be attached to the first wafer W1 by using the first adhesive layer 170. The second semiconductor chip 200 may be arranged such that the first surface 212 of the second substrate 210 of the second semiconductor chip 200 faces the first wafer W1.

The second semiconductor chip 200 may be attached on the first wafer W1 by performing a thermal compression process at a predetermined temperature (e.g., about 400° C. or less). Through the thermal compression process, the second semiconductor chip 200 and the first wafer W1 may be bonded to each other.

In the thermal compression process, the non-conductive film may be liquefied and may have fluidity, and may flow between the second semiconductor chip 200 and the first wafer W1. The non-conductive film having fluidity may flow between the first conductive connection members CB1 and then may be cured to fill a space between the first conductive connection members CB1. A portion of the cured first adhesive layer 170 may protrude beyond a side surface of the second semiconductor chip 200.

Through the thermal compression process, the first conductive bump 232 of the second semiconductor chip 200 may be bonded to the first signal bonding pad 160 of the first semiconductor chip, and the second conductive bump 242 may be bonded to the first dummy bonding pad 162 of the first semiconductor chip.

The second signal chip pad 225 may be electrically connected to the first bonding pad 130 by the first conductive bump 232, the first signal bonding pad 160 and the first through electrode 150.

Referring to FIGS. 18 and 19, a third semiconductor chip 300 may be stacked on the second semiconductor chip 200.

First, processes the same as or similar to the processes described with reference to FIGS. 5 to 15 may be performed to form an individualized third semiconductor chip 300, and processes the same as or similar to the processes described with reference to FIGS. 16 and 17 may be performed to stack the third semiconductor chip 300 on the second semiconductor chip 200.

In some example embodiments of the present inventive concept, the third semiconductor chip 300 may include a third substrate 310, a third wiring layer 320, third signal chip pads 325 and third dummy chip pads 326, third through electrodes 340, and third signal bonding pads 360 and third dummy bonding pads 362. The third wiring layer 320 may be provided on a first surface 312 of the third substrate 310, and third signal chip pads 325 and third dummy chip pads 326, which may be referred to as fifth bonding pads, may be provided on the third wiring layer 320. The third through electrodes 340 may penetrate the third substrate 310, and the third signal bonding pads 360 and the third dummy bonding pads 362, which may be referred to as sixth bonding pads, may be provided on the second surface 314 of the third substrate 310. In addition, the third semiconductor chip 300 may include second conductive connection members CB2 having first conductive bumps 332, which may be disposed on the third signal chip pads 325, and second conductive bumps 342, which may be disposed on the third dummy chip pads 326.

The third semiconductor chip 300 may be stacked on the second semiconductor chip 200 via the second conductive connection members CB2. To adhere the third semiconductor chip 300 to the second semiconductor chip 200, a second adhesive layer 270 may be attached to the third semiconductor chip 300. The second adhesive layer 270 may be formed on the third wiring layer 320 to cover the second conductive connection members CB2. The third semiconductor chip 300 may be attached to the second semiconductor chip 200 by using the second adhesive layer 270. The third semiconductor chip 300 may be arranged such that the first surface 312 of the third substrate 310 of the third semiconductor chip 300 faces the second semiconductor chip 200.

A thermal compression process may be performed to attach the third semiconductor chip 300 to the second semiconductor chip 200. In the thermal compression process, a non-conductive film of the second adhesive layer 270 may be liquefied and may have fluidity, and may flow between the third semiconductor chip 300 and the second semiconductor chip 200. The non-conductive film having fluidity may flow between the second conductive connection members CB2 and may then be cured to fill a space between the second conductive connection members CB2. A portion of the cured second adhesive layer 270 may protrude beyond a side surface of the third semiconductor chip 300.

Through the thermal compression process, the first conductive bump 332 of the third semiconductor chip 300 may be bonded to the second signal bonding pad 260 of the second semiconductor chip 200, and the second conductive bump 342 of the third semiconductor chip 300 may be bonded to the second dummy bonding pad 262 of the second semiconductor chip 200.

The third signal chip pad 325 may be electrically connected to the second signal chip pad 225 by the first conductive bump 332, the second signal bonding pad 260 and the second through electrode 250.

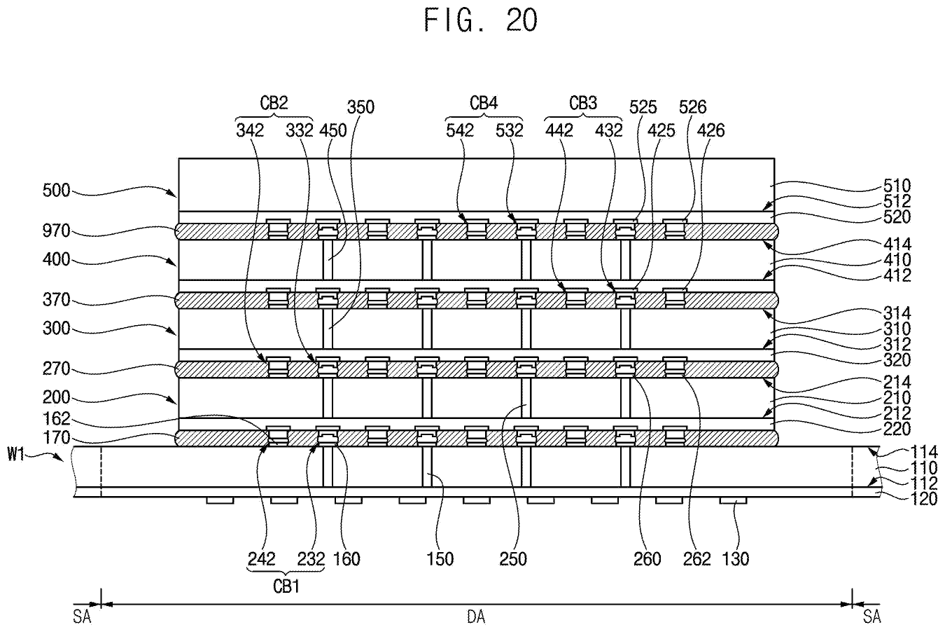

Referring to FIG. 20, processes the same as or similar to the processes described with reference to FIGS. 18 and 19 may be performed to stack a fourth semiconductor chip 400 on the third semiconductor chip 300 and to stack a fifth semiconductor chip 500 on the fourth semiconductor chip 400.

In some example embodiments of the present inventive concept, the fourth semiconductor chip 400 may be attached on the third semiconductor chip 300 by using a third adhesive layer 370. The fourth semiconductor chip 400 may be arranged such that a first surface 412 of a fourth substrate 410 of the fourth semiconductor chip 400 faces the third semiconductor chip 300.

The fourth semiconductor chip 400 may be stacked on the third semiconductor chip 300 via third conductive connection members CB3. A thermal compression process may be performed to attach the fourth semiconductor chip 400 to the third semiconductor chip 300. A first conductive bump 432 of the fourth semiconductor chip 400 may be bonded to the third signal bonding pad 360 of the third semiconductor chip 300 by the thermal compression process, and a second conductive bump 442 of the fourth semiconductor chip 400 may be bonded to the third dummy bonding pad 362 of the third semiconductor chip 300.

A fourth signal chip pad 425 may be electrically connected to the third signal chip pad 325 by the first conductive bump 432, the third signal bonding pad 360 and the third through electrode 350.

Similarly, the fifth semiconductor chip 500 may be attached to the fourth semiconductor chip 400 by using a fourth adhesive layer 470. The fifth semiconductor chip 500 may be arranged such that a first surface 512 of a fifth substrate 510 of the fifth semiconductor chip 500 faces the fourth semiconductor chip 400.

The fifth semiconductor chip 500 may be stacked on the fourth semiconductor chip 400 via fourth conductive connection members CB4. A thermal compression process may be performed to attach the fifth semiconductor chip 500 to the fourth semiconductor chip 400. A first conductive bump 532 of the fifth semiconductor chip 500 may be bonded to a fourth signal bonding pad 460 of the fourth semiconductor chip 400 by the thermal compression process, and a second conductive bump 542 of the fifth semiconductor chip 500 may be bonded to a fourth dummy bonding pad 462 of the fourth semiconductor chip 400.

A fifth signal chip pad 525 may be electrically connected to the fourth signal chip pad 425 by the first conductive bump 532, the fourth signal bonding pad 460 and a fourth through electrode 450.

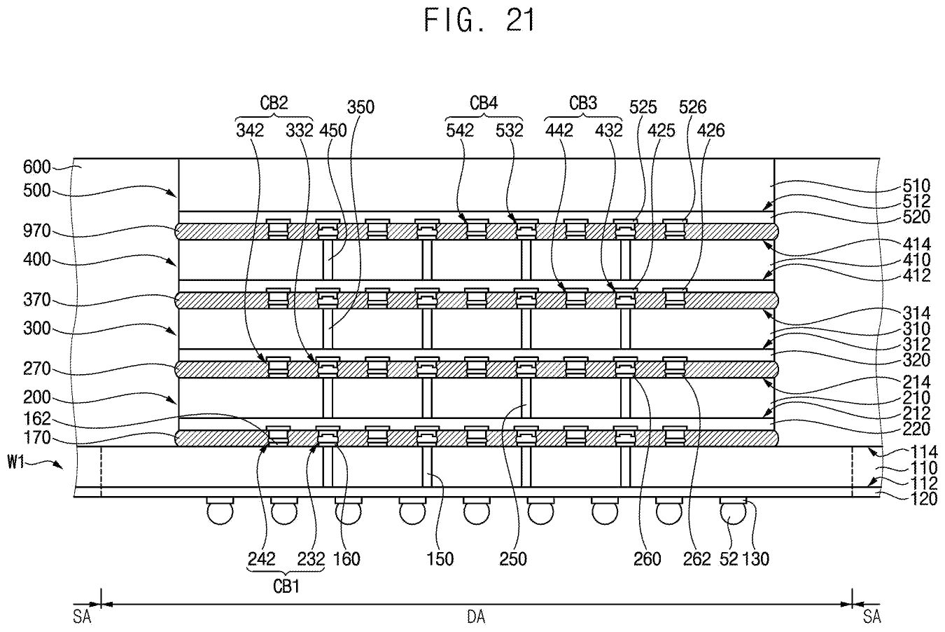

Referring to FIG. 21, a molding member 600 may be formed on the first wafer W1 to cover side surfaces of the second, third, fourth and fifth semiconductor chips 200, 300, 400 and 500.

In some example embodiments of the present inventive concept, the molding member 600 may be formed to fill gaps between the first, second, third, fourth and fifth semiconductor chips 100, 200, 300, 400 and 500. The molding member 600 may expose an upper surface of the fifth semiconductor chip 500; however, the present inventive concept is not limited thereto. For example, the molding member 600 may be formed using a polymer material such as an epoxy molding compound (EMC).

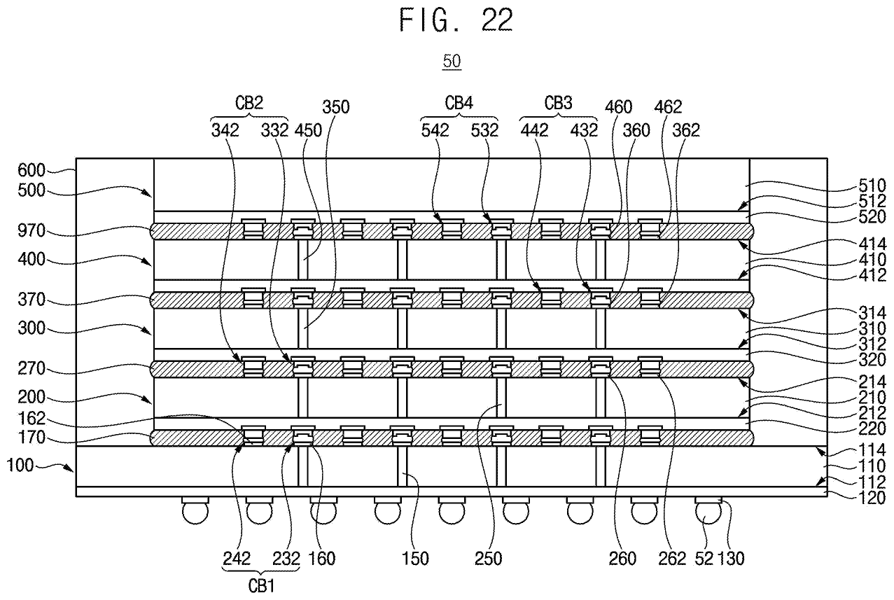

Referring to FIG. 22, after conductive bumps 52 are formed on the first bonding pads 130 of the first semiconductor chip 100, the first wafer W1 may be cut along the scribe lane region SA to form a first semiconductor chip 100, and the molding member 600 may be cut with the scribe lane region SA to complete the semiconductor package 50 of FIG. 2.

The semiconductor package may include semiconductor devices such as logic devices or memory devices. For example, the semiconductor package may include logic devices such as central processing units (CPUs), main processing units (MPUs), or application processors (APs), or the like. In addition, the semiconductor package may include, for example, volatile memory devices such as DRAM devices, or HBM devices, or non-volatile memory devices such as flash memory devices, PRAM devices, MRAM devices, or ReRAM devices.

While the present inventive concept has been described with reference to example embodiments thereof, it will be understood by those of ordinary skill in the art that various changes in form and details may be made thereto without departing from the spirit and scope of the present inventive concept.

What is claimed is:

1. A semiconductor package comprising:
a first semiconductor chip including a first substrate having a first surface and a second surface opposite to the first surface, first through electrodes, first signal bonding pads, and first dummy bonding pads, wherein the first through electrodes penetrate the first substrate, wherein the first signal bonding pads are provided on the second surface and are electrically connected to the first through electrodes, and wherein the first dummy bonding pads are provided on the second surface and are electrically insulated from the first through electrodes;
a second semiconductor chip stacked on the second surface of the first semiconductor chip, wherein the second semiconductor chip includes a second substrate having a third surface and a fourth surface opposite to the third surface and a plurality of second chip pads that are provided on the third surface and that are respectively corresponding to the first signal bonding pads and the first dummy bonding pads;
first conductive bumps interposed between the first signal bonding pads and the corresponding second chip pads; and
second conductive bumps interposed between the first dummy bonding pads and the corresponding second chip pads,
wherein each of the first conductive bumps includes a signal bump pad and a first solder bump, wherein the signal bump pad is provided on a second chip pad of the plurality of second chip pads and has a dimple in an upper portion thereof, and wherein the first solder bump is provided on the signal bump pad, and
each of the second conductive bumps includes a thermal bump pad and a second solder bump, wherein the thermal bump is provided on a second chip pad of the plurality of second chip pads and has a flat upper surface, and wherein the solder bump is provided on the thermal bump pad.

2. The semiconductor package of claim 1, wherein the signal bump pad has a first thickness, and the thermal bump pad has a second thickness greater than the first thickness.

3. The semiconductor package of claim 2, wherein the first thickness of the signal bump pad is within a range of about 1 μm to about 5 μm, and the second thickness of the thermal bump pad is within a range of about 3 μm to about 7 μm.

4. The semiconductor package of claim 1, wherein the signal bump pad includes nickel, and the thermal bump pad includes copper.

5. The semiconductor package of claim 1, wherein the thermal bump pad includes a first plating pad and a second plating pad provided on the first plating pad.

6. The semiconductor package of claim 5, wherein the first plating pad includes copper, and the second plating pad includes nickel.

7. The semiconductor package of claim 1, wherein the signal bump pad has a first thermal conductivity, and the thermal bump pad has a second thermal conductivity greater than the first thermal conductivity.

8. The semiconductor package of claim 1, wherein each of the signal bump pad and the thermal bump pad have a diameter within a range of about 10 μm to about 20 μm.

9. The semiconductor package of claim 1, further comprising:
an adhesive layer filling spaces between the first conductive bumps and the second conductive bumps and between the first semiconductor chip and the second semiconductor chip, and attaching the first and second semiconductor chips to each other.

10. The semiconductor package of claim 1, wherein the second semiconductor chip includes a second wiring layer provided on the third surface of the second substrate, and
the second chip pads are provided on the second wiring layer.

11. A semiconductor package comprising:
first, second, third and fourth semiconductor chips sequentially stacked on one another via conductive connection members,
wherein each of the first, second, third and fourth semiconductor chips includes a substrate having a first surface and a second surface opposite to each other, and signal chip pads and dummy chip pads provided on the first surface of the substrate,
wherein each of the conductive connection members include first conductive bumps and second conductive bumps, wherein the first conductive bumps are disposed on the signal chip pads, and wherein second conductive bumps are disposed on the dummy chip pads,
wherein each of the first conductive bumps includes a signal bump pad and a first solder bump, wherein the signal bump pad is provided on the signal chip pad and has a dimple in an upper portion thereof, and wherein the first solder bump is provided on the signal bump pad, and
wherein each of the second conductive bumps includes a thermal bump pad and a second solder bump, wherein the thermal bump pad is provided on the dummy chip pad and has a flat upper surface, and wherein the second solder bump is provided on the thermal bump pad.

12. The semiconductor package of claim 11, wherein each of the first, second and third semiconductor chips includes through electrodes penetrating the substrate, and
the first conductive bumps are electrically connected to the through electrodes, and the second conductive bumps are electrically insulated from the through electrodes.

13. The semiconductor package of claim 11, wherein the signal bump pad has a first thickness, and the thermal bump pad has a second thickness greater than the first thickness.

14. The semiconductor package of claim 11, wherein the signal bump pad includes nickel, and the thermal bump pad includes copper.

15. The semiconductor package of claim 11, wherein the thermal bump pad includes a first plating pad and a second plating pad provided on the first plating pad.

16. The semiconductor package of claim 15, wherein the first plating pad includes copper, and the second plating pad includes nickel.

17. The semiconductor package of claim 11, wherein the signal bump pad has a first thermal conductivity, and the thermal bump pad has a second thermal conductivity greater than the first thermal conductivity.

18. The semiconductor package of claim 11, further comprising:
adhesive layers filling spaces between the first conductive bumps and the second conductive bumps and between the first, second, third and fourth semiconductor chips, wherein the adhesive layers attach the first, second, third and fourth semiconductor chips to each other.

19. The semiconductor package of claim 11, wherein each of the first, second, third and fourth semiconductor chips includes a wiring layer provided on the first surface of the substrate, and
the signal chip pads and the dummy chip pads are provided on the wiring layer.

20. A semiconductor package comprising:
a buffer die;
first, second, third and fourth memory dies sequentially stacked on the buffer die via conductive connection members; and
adhesive layers disposed between the first to fourth memory dies and attaching the first, second, third and fourth memory dies to each other,
wherein each of the first, second, third and fourth memory dies includes a substrate having a first surface and a second surface opposite to the first surface and signal chip pads and dummy chip pads provided on the substrate,
wherein the conductive connection members include first conductive bumps and second conductive bumps, wherein the first conductive bumps are disposed on the signal chip pads, and the second conductive bumps are disposed on the dummy chip pads,
wherein each of the first conductive bumps includes a signal bump pad and a first solder bump, wherein the signal bump pad is provided on the signal chip pad and has a dimple in an upper portion thereof, and the first solder bump is provided on the signal bump pad, and
wherein each of the second conductive bumps includes a thermal bump pad and a second solder bump, wherein the thermal bump pad is provided on the dummy chip pad and has a flat upper surface, and the second solder bump is provided on the thermal bump pad.
